(19) United States
(12) Patent Application Publication
(10) Pub. No.: US 2012/0012252 A1
(43) Pub. Date: Jan. 19, 2012

(54) PLASMA PROCESSING APPARATUS

(76) Inventors: Hironori Kusumoto, Kudamatsu (JP); Hideki Kihara, Kudamatsu (JP); Tsutomu Nakamura, Hikari (JP); Hidenobu Tanimura, Kudamatsu (JP); Yuuya Mizobe, Hikari (JP)

(21) Appl. No.: 12/856,863

(22) Filed: Aug. 16, 2010

(30) Foreign Application Priority Data
Jul. 14, 2010 (JP) 2010-159259

(51) Int. Cl. H01L 21/465

(52) U.S. Cl. 156/345.24

(57) ABSTRACT

A plasma processing apparatus capable of detecting sealing abnormality of each gate is disclosed. This apparatus includes an outer chamber constituting a vacuum vessel, an inner chamber disposed within the outer chamber for permitting a plasma to be formed in a vacuumed processing chamber as internally provided therein, a workpiece table below the processing chamber for holding thereon a wafer to be processed, a first gate valve disposed in a sidewall of the inner chamber for driving a gate to open and close while the wafer is transferred therethrough, and a second gate valve disposed in a sidewall of the outer chamber for opening and closing a gate while the wafer is transferred therethrough. After the wafer is put on the table, a pressure variation of an intermediate room formed between the inner and outer chambers sealed by the gate valves closed, thereby detecting a decrease in sealing performance.

### BACKGROUND OF THE INVENTION

The present invention relates to a plasma processing apparatus which creates a plasma while simultaneously introducing a processing gas or gases into a pressure-reduced processing chamber within a vacuum vessel and which uses this plasma to apply processing to a substrate-shaped workpiece, such as a semiconductor wafer or the like.

In prior known plasma processing apparatuses for forming a plasma within a vacuum vessel and for using this plasma to process a substrate-like workpiece, such as a semiconductor wafer, to thereby manufacture semiconductor devices, while letting a processing gas or gases be introduced into a processing chamber which is disposed within the vacuum vessel and which is reduced in pressure to a predetermined degree of vacuum, an electric field or a magnetic field is supplied to the interior space of the processing chamber for excitation of the processing gas(es) to thereby create a plasma. This plasma is used to process a film structure of a target object to be processed as laid out on a surface of the semiconductor wafer, thereby forming desired fabrication shapes. For example, the electric field that is introduced from an electrical wave source which is disposed outside of the vacuum vessel is supplied from an antenna which is arranged at an upper part of the processing chamber, for converting a high reactive gas that is introduced into the interior of the processing chamber into a plasma; then, a thin film which is preformed on the wafer surface is processed to have a desired shape based on physical and chemical reactions with charged particles, such as ions, and reactive particles, e.g., radicals, which are contained in the plasma.

This type of plasma processing apparatus is typically arranged to include a vacuum vessel having a processing chamber in its interior, and a vacuum delivery/transfer vessel which is coupled to this vacuum vessel so that their interior spaces are gas-flowably coupled together, wherein a gate is provided for forming a gas flow passage between these internal processing chamber and vacuum transfer vessel. This gate is required to hermetically closed or sealed in order to prevent unwanted invasion of foreign material, such as contaminant particles, by way of the gate in the event that processing is being performed within the processing chamber.

One known example of the plasma processing apparatus having such gate is disclosed in JP-A-2009-64873 (Patent Literature 1). In this prior art apparatus, a first gate valve is provided at the gate that gas-flowably couples together a vacuum transfer vessel to be vacuumized and the interior of a vacuum chamber, for blocking the bidirectional flow of a gas therebetween. The apparatus also includes an inner case which is provided within the vacuum chamber for partitioning and isolating its interior space from the outside environmental space thereof to thereby form a processing chamber, and a second gate valve which is disposed in a space between the vacuum chamber and the inner case in such a manner as to be situated on a side wall of this inner case, for opening and closing an aperture which permits a wafer for use as the workpiece to be conveyed therethrough. By optimally adjusting gas flow rates and pressures of the transfer vessel and processing chamber for adjustment of the gas flow, it is achievable to reduce the number of foreign matter or contaminants behaving to attach during transfer of the wafer to be processed.

### SUMMARY OF THE INVENTION

The above-stated prior art apparatus is encountered with problems because it lacks ample consideration about the following point. More specifically, the second gate valve is merely designed to close during normal processing only; the first gate valve is not closed. Accordingly, when an obstruction takes place at the second gate valve, a leakage can occur whereby an inactive gas or gases on the side of the vacuum transfer vessel enter the interior of the processing chamber so that processing conditions are changed unintentionally, resulting in an appreciable difference of a resultant fabricated shape from the expected one. This poses a problem as to degradation of the yield of the processing. The prior art fails to take this problem into consideration in any way.

One considered solution in this case is to design the plasma processing apparatus to have a detection device, such as a pressure sensor or a monitor of a specific kind of gas, which is disposed in either the processing chamber or the vacuum transfer room, for detecting a pressure variation to thereby detect a decrease in gate valve performance and/or the occurrence of an obstruction. However, the detection of such valve performance degradation is not easy. More precisely, it has been difficult to detect a change in pressure due to gas leakage and a minimal amount of specific kind of gas on the side of the processing chamber which is evacuated by the operation of a vacuum pump and which is set to an ultra-low level of pressure and also on the side of the vacuum transfer room which has a volume that is generally extremely larger than the volume of the processing chamber and which is typically set at a relatively high level of pressure in order to suppress diffusion of gases of high reactivity within the processing chamber.

It is therefore an object of this invention to provide a plasma processing apparatus capable of detecting the seal abnormality of each gate to thereby improve the yield of the processing.

The foregoing object is attainable by providing a plasma processing apparatus which includes an outer chamber constituting a vacuum vessel, an inner chamber disposed on the inner side of the outer chamber for permitting a plasma to be formed in a pressure-reduced processing chamber which is internally provided therein, a workpiece support table which is located at a lower part of the processing chamber within the inner chamber for holding thereon a wafer to be processed by the plasma, a first gate valve disposed in a side wall of the inner chamber for driving a gate to open and close while the wafer is transferred therethrough, and a second gate valve disposed in a side wall of the outer chamber for driving a gate to open and close while the wafer is transferred therethrough, wherein after the wafer is put on the workpiece table, a change in pressure of an intermediate room which is a space between the inner chamber and the outer chamber which are sealed by blockage of the first and second gate valves is detected to thereby detect a decrease in sealing by means of any one of the first and second gate valves.

The object is also attainable by a feature which follows: the processing chamber is set so that its pressure is smaller than a pressure of the intermediate room; and, the sealing of the first gate value is determined to be incomplete in cases where the pressure of the intermediate room is less than a predetermined value.

Further, the object is attainable by a feature which follows: the plasma processing apparatus further includes a vacuum transfer vessel which has a pressure-reduced interior space for use as a transfer room in which the wafer is transferred and which vessel is coupled to the outer chamber for causing their interior spaces to be gas-flowably jointed together, wherein the intermediate room is made smaller in pressure than the transfer room, and wherein the sealing of the first gate value is determined to be incomplete in cases where the pressure of the intermediate room is greater than a prespecified value.

Furthermore, the object is attainable by a feature which follows: after having judged the absence of a decrease in performance of the sealing by virtue of the first and second gate valves, processing of the wafer that is placed within the processing chamber gets started.

Other objects, features and advantages of the invention will become apparent from the following description of the embodiments of the invention taken in conjunction with the accompanying drawings.

### BRIEF DESCRIPTION OF THE DRAWINGS

FIG. 1 is a diagram schematically showing a longitudinal cross-sectional view of a plasma processing apparatus in accordance with one preferred embodiment of the present invention.

FIG. 2 is an enlarged longitudinal sectional diagram showing a part of the plasma processing apparatus in accordance with the embodiment shown in FIG. 1.

FIG. 3 is a pictorial representation of a top plan view of a gate valve unit of the plasma processing apparatus shown in FIG. 2, for explanation of operations of a process gate valve and atmosphere gate valve during transportation of a wafer.

FIG. 4 is a flowchart showing an operation procedure of the plasma processing apparatus in accordance with the embodiment shown in FIG. 1.

### DESCRIPTION OF THE EMBODIMENTS

Currently preferred embodiments of the present invention will be described in detail with reference to the accompanying figures of the drawing below.

### Embodiment 1

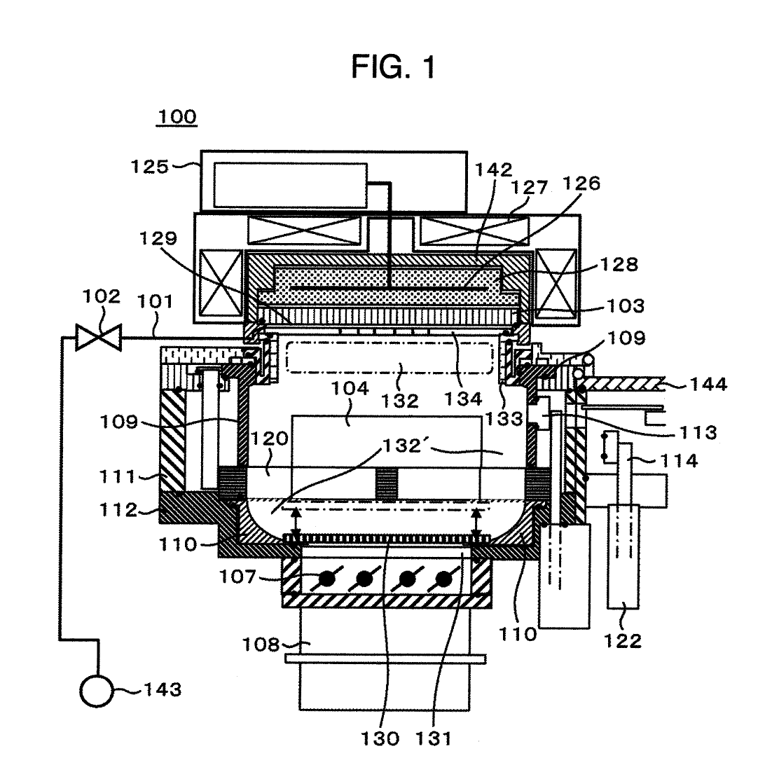

An embodiment of this invention will be explained in detail with reference to FIGS. 1 to 4 below.

FIG. 1 is a diagram schematically showing a longitudinal sectional view of a plasma processing apparatus in accordance with one embodiment of the invention. As shown herein, the plasma processing apparatus, indicated by reference numeral 100, is operatively connected to a vacuum delivery/transfer vessel 144, with an atmosphere gate valve 114 being disposed therebetween. This valve is driven to open and close, thereby permitting those interior spaces of the plasma processing apparatus 100 and vacuum transfer vessel 144 to be gas-flowably coupled together or, alternatively, causing the former to be blocked from the latter. In the state that this atmosphere gate valve 114 is opened, the interior space of the vacuum transfer vessel 144 and the inside space of the plasma processing apparatus 100 are coupled together to allow the air residing in the vessel 144 to flow into the apparatus 100 and vice versa, resulting in the both becoming approximately equal in pressure to each other. When the atmosphere gate valve 114 is kept opened, a semiconductor wafer which is a workpiece to be processed is transferred from the inside of the vacuum transfer vessel 144 to inside of the internal processing chamber, and is then mounted on a workpiece support table 104 which is disposed in this chamber.

In this embodiment, after having detected and affirmed that the wafer is placed on the workpiece table 104, the atmosphere gate valve 114 is driven to close to thereby block the gas flow passage between the interior space of the plasma processing apparatus 100 and that of the vacuum transfer vessel 144 whereby the interior of the plasma processing apparatus 100 is closely sealed; then, the processing is started.

As shown in FIG. 1, the plasma processing apparatus 100 has its upper part at which a discharge room unit is located. This discharge unit is arranged to include a cover member 142 making up a lid or “cap” of the vacuum vessel, an antenna member which is disposed on the inner side of this cover member 142, a magnetic field generation unit having a coil 127 which is disposed on the lateral side and upper side of this antenna member and which is located to surround the discharge unit, and a ceiling member disposed below the antenna member. Additionally, over the magnetic field generator unit, an electrical wave source unit 125 is laid out for supplying electric waves of ultra-high frequency (UHF) band and very high frequency (VHF) band to be radiated by the antenna member. This antenna member has a flat plate-shaped antenna 126 which is made of an electrically conductive material, such as stainless steel (SUS) or the like, and which is disposed inside of the cover member 142, and at least one ring-like dielectric body 128 which is disposed between the antenna 126 and the cover member 142 for electrical insulation therebetween while at the same time conducting an electric wave(s) radiated from the antenna 126 toward the underlying ceiling member side.

The ceiling member has a quartz plate 103 which is made of a chosen dielectric material, e.g., quartz or else, for conducting the incoming electric wave toward the inside of the underlying processing chamber, and a shower plate 134 which is disposed under the quartz plate 103 and has a plurality of openings or holes that are formed therein for dispersion and introduction of a process gas for the processing use as supplied thereto toward inside of the processing chamber.

A space which is defined below the shower plate 134 and over the workpiece table 104 is for use as a discharge room 132, in which a plasma is created by mutual interaction of the supplied process gas with an electric wave which is introduced by way of the quartz plate 103 and a magnetic field that is fed from the magnetic field generator unit. This discharge room 132 is surrounded by a discharge room inner side wall member 133 which is constituted from a dielectric member having a circular cylindrical shape, which is made of quartz or else and high in tolerability against the plasma. Furthermore, a narrow gap space is formed between the quartz plate 103 and the shower plate 134. To this gap space, the process gas to be supplied to the discharge room 132 is first supplied, and is then flown into the discharge room 132 through the shower plate 134 and next through the above-stated holes that couples the gap space and the discharge room 132 together for permitting penetration of the flowing process gas therethrough. The gap space becomes a buffer room 129 which is provided to allow the process gas to disperse or scatter from the plurality of holes and then flow into the discharge room 132. This process gas is supplied from a controller 143 for adjustment of the supply amount of a fluid, such as a gas or else, by way of a process gas line 101 and a process gas shut-off valve 102.

One or more than one chamber is provided on the inner side of a couple of outer chambers 111 and 112 which are disposed at upper and lower parts while constituting an external wall of the vacuum vessel of the plasma processing apparatus 100, which has a multiple chamber structure with one of them being disposed on the inner side of the other. In this embodiment, it has two inner chambers and two outer chambers. More specifically, an inner chamber 109 is equipped on the inside of an upper outer chamber 111 whereas an inner chamber 110 is located inside a lower outer chamber 112. In short, two upper and lower inner chambers 109 and 110 are equipped. The workpiece table 104 is disposed within the inner chamber 109, 110, wherein an interior space of the innermost chamber constitutes a vacuum vessel 132′ in which a plasma is formed and in which gasses and reaction products are forced to flow for exhaust to the outside.

This discharge room 132′ is gas-flowably coupled with the overlying discharge room 132 and is arranged to be capable of coupling with a space between the inner chamber 109 and the outer chamber 111 while being reduced in pressure or “depressurized” by an evacuation device; in addition, the discharge room 132′ is disposed to enable the plasma and gases plus reaction products residing within the discharge room 132 to flow away in the event that the wafer is processed.

For causing the wafer that is a to-be-processed object to be stably mounted on the workpiece table 104 within the inner chamber 109, 110, it becomes necessary to employ a gate which enables the wafer to be transferred to the inner chamber 109 or 110. Further needed is a valve which drives the above-stated valve to open and close for hermetically sealing this valve, and blocks and gas-flowably couples together the inside and outside spaces of this chamber.

This embodiment has the atmosphere gate valve 114 which opens or air-tightly closes the gate that is provided between the inside of the plasma processing apparatus 100 and the inside of the vacuum transfer vessel 144 to thereby gas-flowably couple them together or block the both, and a process gate valve 113 which releases or hermetically blocks the inside and outside of the inner chamber 109 to thereby gas-flowably couple them together or shuts off any gas flow between the both. The atmosphere gate valve 114 is disposed to overlie an inner side wall of the vacuum transfer vessel 144 and is arranged to be driven by a drive device 122 so that it is movable up and down and also movable in the horizontal direction, for air-tightly closing or opening the gate over the inner side wall. In addition, within the outer chamber 111 making up the vacuum vessel, a gate is provided at a position for gas-flowable coupling with the gate on the side of the vacuum transfer vessel 144 when the vacuum transfer vessel 144 and the plasma processing apparatus 100 are connected together.

The lower inner chamber 110 is located under a block of the workpiece table 104; at a central part of this inner chamber 109, 110, an opening or aperture is laid out. This aperture is gas-flowably coupled with the evacuation device having an exhaust valve 107 and a vacuum pump 108 as disposed below the inner chamber 110 and beneath the workpiece table 104, and is a part for penetrative flow of gases residing within the inner chamber 109, which gases flow around the workpiece table 104. More specifically, both a space between beam-like support members 120 around the workpiece table 104 and a space within the lower inner chamber 110 beneath the workpiece table 104 serve as an exhaust pathway or “channel” for causing the processing gas and residual in-plasma particles plus reaction product particles within the plasma processing apparatus 100 to flow therein for external exhaust.

The exhaust valve 107 that is the evacuation device of the plasma processing apparatus 100 is a shutter-type exhaust valve which has a plurality of plate-like shutters capable of gas-flowably coupling together the underlying vacuum pump 108 and the interior space of inner chamber 110 or establishing shielding therebetween and which rotates these shutters for variably adjusting the area of a presently opening exhaust passage to thereby adjust the exhaust gas flow rate and velocity. As apparent from the explanation above, in this embodiment, the evacuation device is disposed below the workpiece table 104, in particular, immediately beneath this table. The plasma and processing gas plus reaction products residing in the upper space of the workpiece table 104 within the inner chamber 109 behave to flow in the exhaust pathway up to the exhaust valve 107 through a space around the workpiece table 104 and a space within the inner chamber 110 that is located below this table.

In this embodiment, the vacuum evacuation device includes the exhaust valve 107 having the plurality of rotatable plate-shaped shutters and the vacuum pump 108 located thereunder, wherein the exhaust valve 107 is such that the valve is disposed immediately below the workpiece table 104. As shown in FIG. 1, the plurality of shutters are disposed substantially horizontally (i.e., in the direction of a wafer surface) and are arranged so that each shutter rotates about its axis or shaft attached thereto to thereby adjust the area for allowing gases to flow between the above-stated aperture of the inner chamber 110 and the vacuum pump 108. By letting these shutter shafts continue rotating, the plates of respective adjacent shutters come into contact with each other to thereby seal and hermetically block the aperture. In addition, the gas-flowing area becomes the largest when the plates of respective shutters are in almost parallel with a direction perpendicular to the surface of the workpiece table 104 (i.e., vertical direction). The exhaust valve 107 has a drive device, such as an electric motor or the like, for adjustment of rotations of these shutters, although not specifically illustrated in FIG. 1. The evacuation device adjusts the exact amount of an exhaust gas and the velocity thereof by adjustment of the opening area of these shutters and the drive of the vacuum pump 108.

Additionally, below the workpiece table 104 and over the exhaust valve 107, an exhaust gate plate 130 is provided which covers the upper part of an exhaust aperture gate 131 that is provided in the lower outer chamber 112 and which plate opens and closes this gate (i.e., forms an opening and blocks it off). This exhaust gate plate 130 has a substantially round disc-like shape and has, as its part, at least one pair of externally extending arm portions which are partially formed at an outer circumferential edge thereof. By causing the upper end of a pusher that is disposed below the arm portions to operate in upward and downward directions, the arm portions coupled to this upper end are driven to rise up and drop down, thereby driving the exhaust opening to open and close. This exhaust gate plate 130 is specifically arranged so that its downward projection plane is received within a projection plane of the overlying workpiece table 104 and, at the same time, a projection plane of the arm portion is received within a projection plane of the overlying support beam 120 or, alternatively, at least partly overlaps the projection plane.

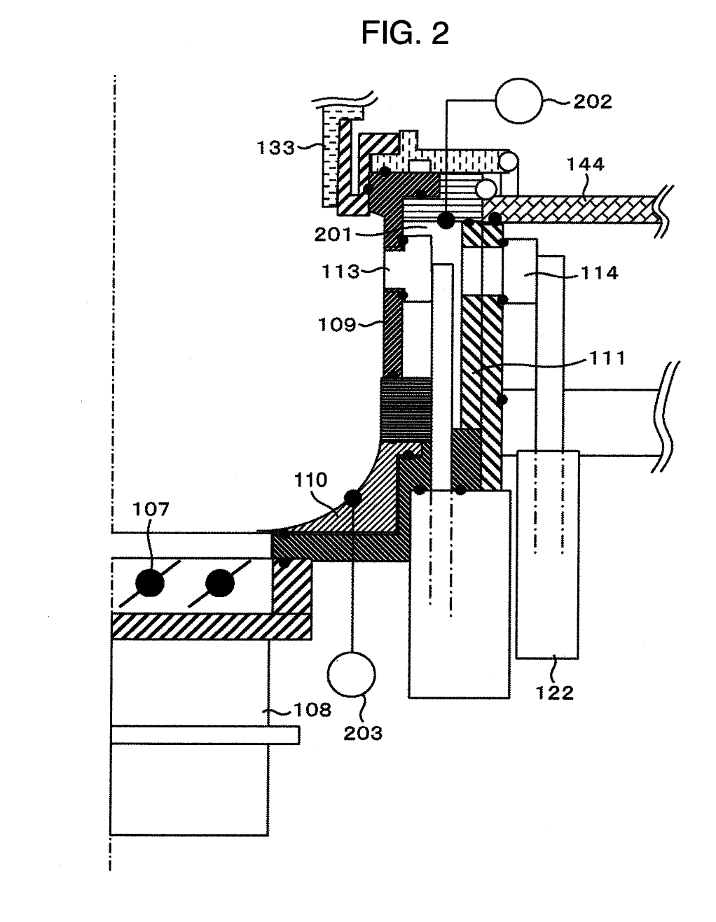

FIG. 2 is a longitudinal sectional diagram showing, in an enlarged manner, one part of the plasma processing apparatus of the embodiment shown in FIG. 1. Particularly, this diagram is the one that enlargedly shows a nearby part of the process gate valve 113 and atmosphere gate valve 114. Note here that regarding the parts or components stated supra in conjunction with FIG. 1, explanations thereof will be eliminated herein. Also note that in FIG. 2, an illustration of the workpiece table 104 is omitted for illustration purposes only.

In this embodiment, the process gate valve 113 which is disposed over the side wall of the inner chamber 109 for opening and closing the aperture of the gate that allows a wafer to pass therethrough for delivery and the atmosphere gate valve 114 which opens and closes the aperture of the gate that is disposed over the outer chamber 111 and the sidewall of vacuum transfer vessel 144 are such that each blocks the gate for providing airtight sealing between inside and outside in the state that the wafer is mounted and stably held on the workpiece table 104 within the inner chamber 109. With this arrangement, the processing chamber within the inner chamber 109 and the vacuum transfer room within the vacuum transfer vessel 144 and also a space defined therebetween, which is the space between the inner chamber 109 and the outer chamber 111, are air-tightly partitioned and thus become independent spaces respectively.

On the other hand, within a time period up to blockage of the above-stated two gate valves, including a period in which a wafer is being transferred, the gate is opened whereby these spaces are gas-flowably jointed together into a single space with an inactive gas, such as argon (Ar) or else, being fed into either the processing chamber or the vacuum transfer room, which will later be evacuated by the vacuum pump 108 or an evacuation device for use with the vacuum transfer room. In this state, these spaces are set at the same level of pressure or, alternatively, set to approximate pressure levels which are deemed almost the same in value as each other.

After the wafer is mounted on the workpiece table 104, electrical power is supplied to an electrostatic suction electrode(s) (not depicted) disposed within the workpiece table 104, forcing the wafer to be tightly attached to and held on the workpiece table 104. When a workpiece transfer robot within the wafer-delivered vacuum transfer room exits and goes to inside of the vacuum transfer room, the drive device 122 is rendered operative in response to receipt of a command or instruction signal from a control device (not shown) so that the atmosphere gate valve 114 moves upward in the interior of the vacuum transfer room, thereby closing for blockage the aperture of the gate of the inner side wall of the vacuum transfer vessel 144.

Thereafter, the interior of the processing chamber within the inner chamber 109 is evacuated for pressure reduction with the aid of operations of the exhaust valve 107 and vacuum pump 108, in order to provide preparation for execution of the processing to be performed in the processing chamber. Owing to this evacuation operation, the interior of the processing chamber within the inner chamber 109 constituting the inner space of the outer chamber 111 and the space between the inner chamber 109 and outer chamber 111 are set to a pressure which is lower than the pressure within the vacuum transfer room that was air-tightly partitioned by the atmosphere gate valve 114.

When it is detected by the control device which has received an output from a pressure sensor 202 or 203 that the pressure of the space within the outer chamber 111 became smaller than a predetermined pressure P0, the control device generates a command and sends it to a drive device of the process gate valve 113 in order to block the gate on the side wall of the inner chamber 109 by the process gate valve 113. By an operation of this drive device, the process gate valve 113 moves from a lower position of the gate which does not become any obstruction against the wafer conveyance to an upper position and further moves horizontally, thereby forcing the surface of a seat having a valve sealing function to come into contact with the outer side wall in the periphery of the gate over the inner chamber 109 to thereby air-tightly seal the space between the inside and outside of the gate in such a manner as to seal the interior of the inner chamber 109.

After this process, the evacuation owing to the operation of the vacuum pump 108 is continued so that the pressure within the inner chamber 109 is reduced to a suitable pressure level which is required for contaminant removal and execution of the processing. Thereafter, a processing gas is introduced into the processing chamber which overlies the wafer from a plurality of through-holes (not depicted) which are formed in the shower plate 134 at upper part of the processing chamber; then, the processing gas is excited by mutual interaction of an electric field from the antenna 126 and a magnetic field from the coil while maintaining a pressure of a prespecified vacuum degree, thereby to create a plasma; next, while charged particles in this plasma are attracted by induction onto the wafer, reactive particles physically and chemically react with the material of a film to be processed, which constitutes a film structure that was disposed in advance on the wafer surface so that etch processing is performed.

In a case where the gate that is disposed at the part of the side wall at which the outer chamber 111 and vacuum transfer vessel 144 are gas-flowably coupled together is opened during execution of the processing after the plasma was formed within the inner chamber 109, airtight sealing between the inside and outside of the processing chamber is achieved by the process gate valve 113. For example, in the state that the atmosphere gate valve 114 is at a position for opening the gate, the process gate valve 113 is kept closed within a time period of from the mounting and sucked holding of a wafer on the top surface of the processing table 104 up to completion of the above-noted processing.

In other words, this process gate valve 113 is also used as a gate valve operatively associated with the vacuum transfer vessel 144 for retaining conditions of the processing being performed within the vacuum vessel of the plasma processing apparatus 100. Further, in this state, the vacuum transfer room within the vacuum transfer vessel 144 and the space between the outer chamber 111 and inner chamber 109 are gas-flowably coupled together by the gate that is opened and closed by the atmosphere gate valve 114; so, these are regarded as a single space, to which an inactive gas to be fed into the vacuum transfer room, such as Ar gas, is supplied in a similar way.

Alternatively, in cases where a leakage is generated from the gate due to a decrease in sealing performance of the process gate valve 113 or destruction of the sealing by unwanted presence of foreign matter, e.g., contaminants or the like, the inactive gas which was fed into the vacuum transfer vessel 144 behaves to enter inside of the processing chamber that is at a lower pressure, resulting in a change in process conditions of the processing being performed within the processing chamber. However, in view of the fact that an inactive gas for use as the diluent gas is typically supplied to the processing chamber interior space along with a plurality of kinds of processing gases, it has been difficult to accurately detect an external gas that was intruded or “invaded” thereinto due to occurrence of the abnormality of a valve seal.

In this embodiment, as shown in FIG. 2, the atmosphere gate valve 114 adjusts, under control of the control device, the interior of the gate that is openable and closable thereby in such a way as to set it in the sealed state except for a time period in which the workpiece transfer robot within the vacuum transfer room transfers a wafer which passes through the gate. With this operation, both the process gate valve 113 and the atmosphere gate valve 114 operate to set the gate in the sealed state during processing. With this feature, the space defined between the inner chamber 109 and outer chamber 111 becomes a small volume of intermediate compartment or room 201 which is tightly sealed by the above-stated two valves.

By having the small-volume space to be sealed by two valves in this way, it is possible to accurately detect or sense a change in pressure due to leakage at these valves. Regarding the determination as to which one of these valves undergoes such leakage, this is performable by detection of a variation of the pressure of the intermediate room 201, which will be referred to as “mid room” hereinafter.

For example, in a case where leakage takes place at the process gate valve 113, the plasma processing apparatus 100 of this embodiment is such that the processing chamber is set to less in pressure than the mid room 201; so, a leakage gas is expected to flow from the mid room 201 toward the processing chamber, resulting in a decrease in pressure of the mid room 201 in cases where no leakage occurs at the atmosphere gate valve 114. On the other hand, in case leakage occurs at the atmosphere gate valve 114, the vacuum transfer vessel 144 is higher in pressure than the mid room 201 whereby a leakage gas behaves to flow from the vacuum transfer vessel 144 to the mid room 201 so that the mid room 201 increases in pressure.

This embodiment is arranged to have a pressure sensor 203 which is provided in the inner chamber 110 underlying the workpiece table 104 and surrounding the periphery of lower part of the processing chamber and which detects a pressure in the processing chamber, and a pressure sensor 202 which is disposed at a member constituting a ceiling plane of the mid room 201 for detecting a pressure therein. With the use of these sensors, the embodiment apparatus has an arrangement for detecting a present pressure in the outer chamber 111 and an internal pressure of either the mid room 201 or the processing chamber. Output signals of these pressure sensors are sent to the control device. This control device that received such signals detects pressure values and with-time variations thereof by using an arithmetic computing/calculation unit as internally provided therein.

In case it was judged by the control device that the pressure is abnormal, the occurrence of such abnormality of either the process gate valve 113 or the atmosphere gate valve 114 is reported, by transmitting an error occurrence signal using a communication device, to a user of the plasma processing apparatus 100 and/or an upper-level control device, such as a host computer or the like, which is for control and adjustment of wafer conveyance schedules and operations of a plurality of apparatuses that are located in a building with the plasma processing apparatus 100 and other apparatuses installed therein. Thereafter, error recovery processing of the plasma processing apparatus 100 is performed using a software program which is prestored in a storage device within the control device or, alternatively, downloaded via the communication device from the upper-level control device, such as the host computer.

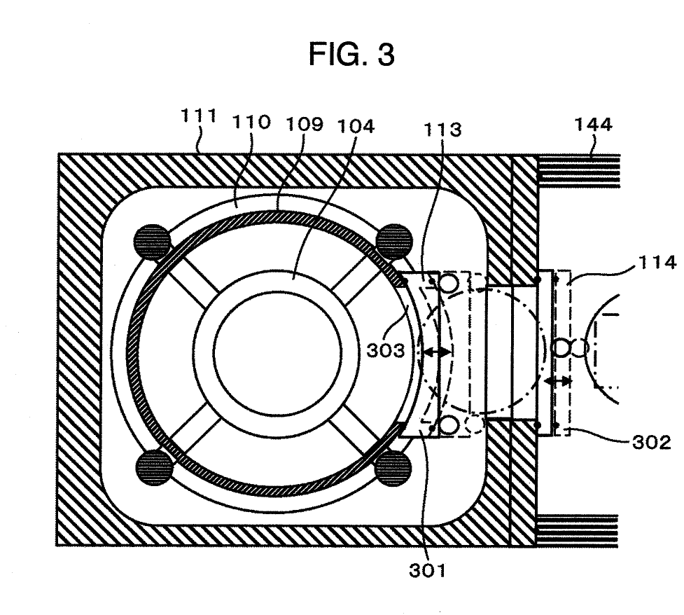

FIG. 3 is a top plan view of the gate valve unit of the plasma processing apparatus 100 shown in FIG. 2, for explanation of operations of the process gate valve 113 and the atmosphere gate valve 114 during transfer of a wafer.

As shown in FIG. 1, when the wafer is transferred, each of the process gate valve 113 and the atmosphere gate valve 114 is located at a position which is beneath the opening/closing gate and which does not become any obstruction against the wafer transfer that is performed by the workpiece transfer robot. Each valve position in this state is indicated by dotted line in FIG. 3. When the wafer is carried into the processing chamber, the process gate valve 113 and the atmosphere gate valve 114 rise up along the side wall as shown in FIG. 2 and then move horizontally (indicated by arrow in FIG. 3) to come into contact with the sidewall whereby each blocks its corresponding gate, thus air-tightly sealing the inner chamber 109 and the vacuum transfer vessel 144 and also inside and outside of the outer chamber 111. This state is indicated by solid line in FIG. 3.

In this embodiment, the process gate valve 113 operates to come into contact with the outer sidewall of the inner chamber 109 having a cylindrical shape to thereby close the aperture of the gate. In view of this, a valve body 301 of the process gate valve 113 has its surface opposing and contacting the sidewall, which surface is arranged to be concaved to have a similar cylindrical shape in order to achieve gapless contact with the curved (cylindrical) sidewall. Furthermore, on a seat plane, a seal member is situated along the curved surface, for offering maximized sealing performance by coming into contact with the cylindrical sidewall around the gate aperture of the inner chamber 109. Meanwhile, as shown in FIG. 3, the atmosphere gate valve 114 is such that a seat plane of its valve body 302 contactable with the inner sidewall of the vacuum transfer vessel 144 has a planar shape as the inner sidewall is a flat surface.

The valve body 301 of the process gate valve 113 also has a projected or salient portion 303 which is at a central part of the seat surface and which is substantially the same in height as the thickness of the sidewall of the inner chamber 109. In a state that the valve body 301 is brought into contact with the outer sidewall of the inner chamber 109 while closing the aperture of the gate of the process gate valve 113, the salient 303 is inserted into the gate. The salient 303 has its top surface which is arranged so that a step-like height difference with respect to the inner sidewall of the inner chamber 109 is made smaller in the state that the gate is sealed, thereby suppressing impairment of the cylindrical shape of the inner sidewall, thus enabling a distribution of the plasma formed in the processing chamber and gases plus reaction products therein to approximate to axial symmetry.

This gives rise to a need for the process gate valve 113 to move the salient 303 in the horizontal direction to thereby vary its projection length or “height”; so, it is coupled with one or more vertically extending support columns or pillars which drive the valve body 303 at both right and left end portions of the valve body 301 in such a way as to enable suppression of compressive force inequality and physical vibration otherwise occurring due to inclination caused by movement of the valve body 303 in the horizontal direction. In order to detect the success or failure of the sealing function owing to the process gate valve 113 having such arrangement, this embodiment is configured to have the above-stated mid room 201 and the arrangement for detecting a pressure and/or gas leakage thereof.

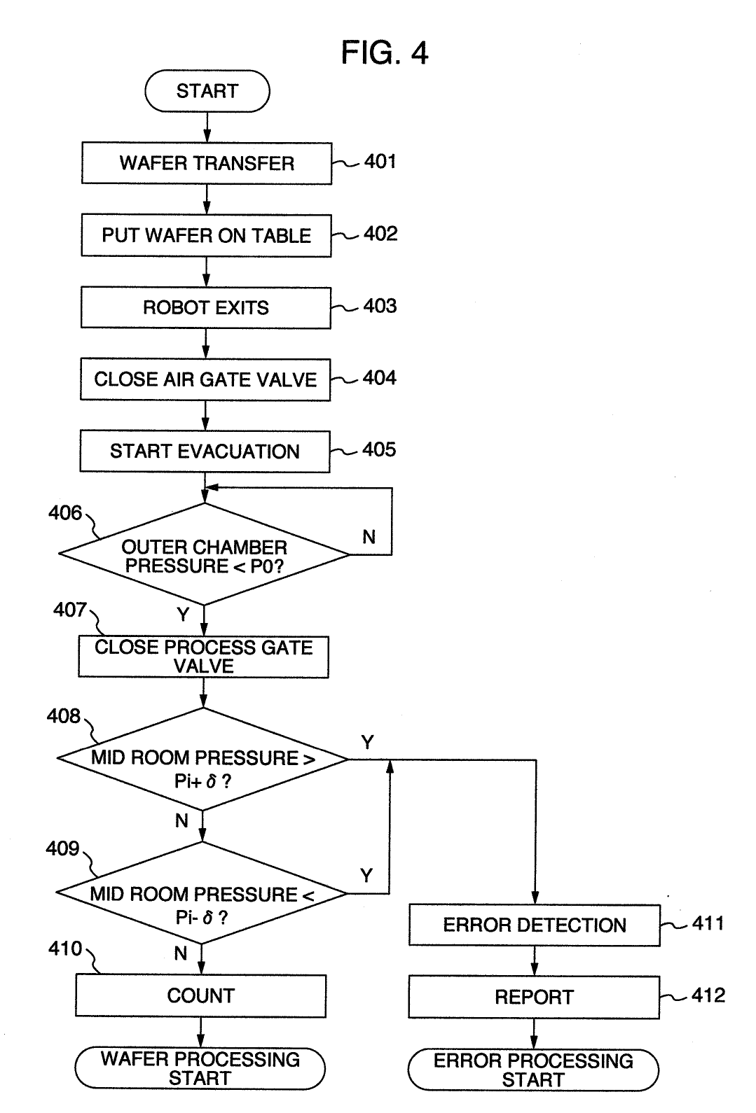

A flow of an operation including the leakage detection in this embodiment is shown in FIG. 4. FIG. 4 is a flowchart of a system procedure of the plasma processing apparatus in accordance with the embodiment shown in FIG. 1.

When wafer processing is performed, a silicon wafer is transferred within the gate which is a wafer carrier passage while being mounted on an arm of the workpiece transfer robot in the vacuum transfer room (at step 401). The wafer that is mounted on the robot arm over the workpiece table 104 is put on a plurality of pins, which are elevated upwardly from a state that these have been received or “retracted” within the workpiece table 104; then, the wafer is passed to the workpiece table 104 (step 402).

The plurality of pins are moved for retraction once again to a position beneath a wafer mount surface of the workpiece table 104 whereby the wafer is put on the mount surface of the workpiece table 104. In this state, direct current (DC) electric power is supplied to the electrostatic suction electrode(s) (not illustrated) within the workpiece table 104 so that the wafer is attached by suction to the workpiece mount surface and stably held thereon.

After having delivered the wafer to the workpiece table 104, the transfer robot exits the processing chamber and the outer chamber 111 and goes to the outside thereof. When it is affirmed by the control device that the robot arm is received within the vacuum transfer vessel 144 (at step 403), the atmosphere gate valve 114 is driven in response to receipt of a command or instruction from the control device so that it comes into contact with the wall surface around the aperture of the gate that is equipped at the inner sidewall of the vacuum transfer room to thereby tightly seal the gate, causing the vacuum vessel interior space constituted from the outer chamber 111 to be partitioned from the vacuum transfer room.

After having closed the atmosphere gate valve 114, the interior of the vacuum vessel is evacuated and reduced in pressure to increase its vacuum degree owing to operations of the vacuum pump 108 and exhaust valve 107 (at step 405). Next, in a state that the vacuum evacuation is being performed, a pressure either in the inner chamber 109 or in the space between the outer chamber 111 and inner chamber 109 is detected based on an output signal from the pressure sensor 202 or 203, wherein this pressure detection will be repeated until this pressure becomes lower than a predetermined value P0 (at step 406). When the pressure is judged by the control device to become less than the pressure value P0, the process gate valve 113 is rendered operative for closing the gate above the sidewall of the inner chamber 109, thereby tightly sealing inside and outside thereof (step 407).

In this state, the space between the inner chamber 109 and outer chamber 111 is closely sealed from the exterior environment, resulting in the mid room 201 being formed. Thereafter, the operations of the vacuum pump 108 and exhaust valve 107 are performed continuously, thereby causing the interior of the processing chamber within the inner chamber 109 to further decrease in pressure, resulting in its vacuum degree is enlarged to reach a target pressure suitable for the intended processing or preparation thereof.

The detection result of a pressure of the mid room 201 which was detected by the pressure sensor 202 is sent to the control device. In responding thereto, the control device detects a present pressure based on this output and determines whether such detected pressure value falls within a range of acceptable values of a predefined pressure Pi. More specifically, an attempt is made to judge whether the pressure of the mid room 201 is smaller than a prespecified upper limit value “Pi+δ” (at step 408). In case the pressure value is judged to be less than the upper limit value Pi+δ, the system procedure proceeds to step 409.

When it is judged that the pressure of the mid room 201 is in excess of the upper limit value Pi+δ, the procedure goes next to step 411 which performs detection of abnormality. At step 409, a decision is made as to whether the pressure of the mid room 201 is less than a prespecified lower limit value “Pi−δ”. When the pressure of the mid room 201 is decided to be less than the lower limit value Pi−δ, the procedure goes to step 411 which performs detection of abnormality. Alternatively, when the pressure is judged to be larger than the lower limit value, it is determined that no leakage takes place at any one of the two valves so that there is no problem concerning the sealing function. If this is the case, the procedure goes to step 410 which performs counting of either an execution number or a time elapsed. When it is detected that either a predefined length of time or an execution time was counted, a decision is made to conclude that there is no problem as to the sealing of the inner chamber 109 or the outer chamber 111 upon execution of the intended processing; thus, the above-stated wafer processing is started.

On the other hand, in case the pressure of the mid room 201 is determined to be greater than the upper limit value Pi+δ at step 408, the following decision is made: a certain kind of abnormality takes place at the atmosphere gate valve 114; the sealing established thereby must have a problem(s); and, the sealing is broken or, alternatively, its function becomes insufficient. Additionally, when the pressure of mid room 201 is judged to be less than Pi−δ at step 409, the following judgment is made: abnormality occurs at the process gate valve 113; the sealing brought thereby has a problem(s); and, the sealing is broken or, alternatively, its function becomes deficient. Upon detection of such abnormality, the control device uses an annunciation device, such as a display device, alarm buzzer or else, to report the occurrence of abnormality at a gate valve at the location judged. Alternatively, an attempt is made (at step 412) to notify it to a host computer by transmitting thereto an abnormality occurrence signal, wherein the host computer is located in a building with the plasma processing apparatus 100 being located therein and is communicably connected or linked to the plasma processing apparatus 100 for controlling semiconductor device fabrication/manufacturing procedures. Thereafter, an operation of the processing with respect to such error and an operation for recovery to proper operation will be performed in accordance with a predefined procedure as recited in advance in a software program(s) or the like.

According to the embodiment stated above, it is possible to provide the intended plasma processing apparatus capable of detecting sealing abnormality of each gate to thereby improve the yield and throughput of the processing.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing apparatus comprising:
an outer chamber constituting a vacuum vessel;
an inner chamber disposed on the inner side of said outer chamber, which is configured to permit a plasma to be formed in a pressure-reduced processing chamber as internally provided therein;
a workpiece table located at a lower part of the processing chamber within said inner chamber, which is configured to hold thereon a wafer to be processed by the plasma;
a first gate valve disposed in a side wall of said inner chamber, which is configured to drive a gate to open and close while the wafer is transferred therethrough; and
a second gate valve disposed in a side wall of said outer chamber, which is configured to drive a gate to open and close while the wafer is transferred therethrough;
wherein, the plasma processing apparatus is configured to detect, after said wafer is put on said workpiece table, a change in pressure of an intermediate room which is a space between said inner chamber and said outer chamber which are sealed by blockage of the first and second gate valves and for detecting a decrease in sealing by any one of said first and second gate valves.

2. The plasma processing apparatus according to claim 1, wherein said processing chamber is made smaller in pressure than said intermediate room, and wherein the sealing of said first gate value is determined to be incomplete in cases where the pressure of said intermediate room is smaller than a predetermined value.

3. The plasma processing apparatus according to claim 1, further comprising a vacuum transfer vessel having a pressure-reduced interior space for use as a transfer room in which said wafer is transferred and being coupled to said outer chamber for causing their interior spaces to be gas-flowably coupled together, wherein said intermediate room is made smaller in pressure than said transfer room and wherein the sealing of said first gate value is determined to be incomplete in cases where the pressure of said intermediate room is greater than a prespecified value.

4. The plasma processing apparatus according to claim 2, further comprising a vacuum transfer vessel having a pressure-reduced interior space for use as a transfer room in which said wafer is transferred and being coupled to said outer chamber for causing their interior spaces to be gas-flowably coupled together, wherein said intermediate room is made smaller in pressure than said transfer room and wherein the sealing of said first gate value is determined to be incomplete in cases where the pressure of said intermediate room is greater than a prespecified value.

5. The plasma processing apparatus according to claim 1, wherein after having judged absence of a decrease in performance of the sealing by virtue of said first and second gate valves, processing of the wafer being placed within said processing chamber is started.

6. The plasma processing apparatus according to claim 2, wherein after having judged absence of a decrease in performance of the sealing by virtue of said first and second gate valves, processing of the wafer being placed within said processing chamber is started.

7. The plasma processing apparatus according to claim 3, wherein after having judged absence of a decrease in performance of the sealing by virtue of said first and second gate valves, processing of the wafer being placed within said processing chamber is started.

8. The plasma processing apparatus according to claim 1, wherein after having detected that the sealing due to said first and second gate valves is incomplete, a seal-incomplete gate valve is reported.

9. The plasma processing apparatus according to claim 2, wherein after having detected that the sealing due to said first and second gate valves is incomplete, a seal-incomplete gate valve is reported.

10. The plasma processing apparatus according to claim 3, wherein after having detected that the sealing due to said first and second gate valves is incomplete, a seal-incomplete gate valve is reported.
